(19) United States
(12) Patent Application Publication
(10) Pub. No.: US 2026/0182323 A1
(43) Pub. Date: Jun. 25, 2026

(54) METHOD OF ADVANCED PACKAGING AND INTERCONNECTION OF THROUGH SILICON VIAS AND ELECTROPLATING SOLUTION

(71) Applicant: Xiamen University, Xiamen (CN)

(72) Inventors: Ke LI, Xiamen (CN); Yi Zhong, Xiamen (CN)

(21) Appl. No.: 18/989,223

(22) Filed: Dec. 20, 2024

(51) Int. Cl. H01L 21/768; C23C 28/02; H01L 23/498

(52) U.S. Cl. CPC H10W 20/043; C23C 28/023; H10W 20/055; H10W 70/635

(57) ABSTRACT

A method of advanced packaging and interconnection of through silicon vias (TSVs) with high aspect ratios, it includes deposition of a seed layer, a plasma treatment o, and filled by electroplating copper.

### FIELD OF THE DISCLOSURE

The present disclosure relates to the field of packaging technology, and specifically relates to a method of advanced packaging and interconnection of through silicon vias (TSVs) with a high aspect ratio and an electroplating solution.

### BACKGROUND OF THE DISCLOSURE

With the continuous development of semiconductor technology, advanced packaging has become an indispensable and important part of the integrated circuit industry. The current advanced packaging technology mainly comprises six important technologies, such as flip chip packaging, wafer-level chip scale packaging, fan-out packaging, 3D wafer-level chip scale packaging, 2.5D packaging, and 3D IC integration. These packaging methods use a combination of different packaging processes, such as bumps, rewiring layers, chip-wafer/wafer-wafer, through silicon vias (TSVs), and stacking to form different packaging methods to enhance performance, reduce size, and maintain high reliability at the same time. Most of the packaging technologies are closely related to wafer-level packaging, and advanced packaging is also developing towards system integration, high speed, high frequency, three dimensions, and ultra-fine interconnection spacing. 3D wafer-level packaging has attracted much attention due to its ability to maximize space utilization and significantly improve integration density. With respect to three-dimensional packaging, multiple chips are stacked vertically, so an interconnection method between chips is particularly important. TSV interconnection technology is usually combined with a micro-bump technology and a chip thinning technology. A vertical signal connection between the chips is one of core technologies of a three-dimensional integrated circuit (3DIC).

The TSVs with a high aspect ratio are more important in interconnection density aspects, which can reduce a chip footprint while maintaining high signal quality. However, the increasing aspect ratio of the TSVs has brought great challenges to manufacturing processes, such as deep via etching, TSV filling, and bonding. The TSV filling is a crucial part, which accounts for 40% of a total cost of TSV. In the TSV filling, appropriate additives play a vital role in controlling properties of a filling solution and ensuring filling effects. Development of the advanced packaging is an important trend in the integrated circuit industry, and the 3D wafer-level packaging based on TSV is a dominant direction of development. With the TSVs with the high aspect ratio becoming popular, an improvement of a filling technology using additives is crucial to ensure a low cost and a high output of TSV technology. With respect to the TSVs with the high aspect ratio, especially the TSVs with an aspect ratio of no less than 15, seed layers with an entire coverage of the TSVs are difficult form due to insufficient coverage the common physical vapor deposition (PVD) technologies, so atomic layer deposition (ALD) Cu or chemical copper plating is commonly used. However, a deposition rate of the ALD technology is slow and cost is high. A process of the chemical copper plating is complex, and a maintenance cost of a plating solution is high.

### BRIEF SUMMARY OF THE DISCLOSURE

The objective of the present disclosure is to overcome the defects of the existing techniques and provide a method of advanced packaging and interconnection of through silicon vias (TSVs) with a high aspect ratio and an electroplating solution. The method can upwardly fill the TSVs with the high aspect ratio and achieve ultra-conformal filling using a direct current (DC)/pulse power supply and a vertical electroplating technology, and the method has good copper filling ability.

In order to achieve the aforementioned objective, a first technical solution of the present disclosure is as follows. The method of the advanced packaging and interconnection of the TSVs with the high aspect ratio, the method comprises steps of:
(1) depositing a copper seed layer on a surface of the TSVs of a sample using physical vapor deposition (PVD);
(2) performing a plasma treatment on the sample treated in the step 1; and
(3) electroplating the sample treated in the step 2.

Further, the sample is a breakout board for packaging with the TSVs, hole diameters of the TSVs are less than 5 μm, and an aspect ratio of the TSVs are greater than 10.

Further, the depositing the copper seed layer in the step 1 comprises: depositing a Ti layer with a thickness of 50-3000 nm as a barrier layer, and depositing the copper seed layer with a thickness of 5-5000 nm over the Ti layer.

Further, the performing plasma treatment in the step 2 comprises performing plasma treatment for 3-7 minutes.

Further, the electroplating in the step 3 comprises electroplating the sample treated in the step 2 with a current having a current density of 0-4 amps/dm² (A/dm²) for 30-60 minutes at a temperature of 20-30° C.

In order to achieve the aforementioned objective, a second technical solution of the present disclosure is as follows. An electroplating solution for electroplating copper using the method of the advanced packaging and interconnection of the TSVs with the high aspect ratio, the electroplating solution comprises sulfuric acid, copper sulfate, chloride ions, a brightener, an inhibitor, and a leveler.

Further, a concentration of the copper sulfate is 80-300 g/L, a concentration of the sulfuric acid is 20-120 g/L, and a concentration of the chloride ion is 10-200 ppm.

Further, the brightener is a mixture of one or more of poly (sodium 3,3′-dithiodipropane sulfonate), sodium thiazolinyl dithio propane sulfonate, sodium alcohol sulfur propane sulfonate, sodium 3-sulfhydryl-1-propane sulfonate, sodium dimethylformamide propane sulfonate, or sodium 3-[[(dimethylamino)thioxomethyl]thio]propane sulphonate, and a concentration of the brightener is 0.5-100 ppm.

Further, the inhibitor is a mixture of one or more of polyethylene glycol, polypropylene glycol, expandable polyethylene 2000 (EPE2000), expandable polyethylene 2900 (EPE2900), or expandable polyethylene 3500 (EPE3500), and a concentration of the inhibitor is 10-1000 ppm.

Further, the leveler comprises at least one of an onium salt or a polyamine, and a concentration of the leveler is 0.5-100 ppm.

Further, the onium salt comprises a carbonium salt or a phosphonium salt.

Further, when the onium salt is the carbonium salt: the carbonium salt comprises one or more of a five-membered ring or a six-membered ring; when the five-membered ring or the six-membered ring is a heterocyclic ring, the heterocyclic ring comprises one or more of C, N, O, or S atoms; the five-membered ring or six-membered ring is connected to at least one of alkyl, phenyl, or alkenyl; and the five-membered ring or six-membered ring has positive charges of no less than one; and when the onium salt is the phosphonium salt, a group connected to phosphorus in the phosphonium salt is an alkyl, benzene ring, or olefin.

Further, when the leveler is the polyamine, the polyamine comprises a polyquaternary ammonium salt, wherein an N atom of a single chain molecule of the polyquaternary ammonium salt is positively charged, and the polyquaternary ammonium salt has a molecular weight of 10000-40000 and contains a carbon-carbon double bond.

Compared with the existing techniques, the present disclosure has the following advantages.
1. The physical vapor deposition (PVD) of the present disclosure has high coverage and can achieve deposition of the copper seed layer within a high aspect ratio so as to compensate for the deficiencies of insufficient coverages of the conventional PVDs;
2. The electroplating solution of the present disclosure has strong applicability and can fill the TSVs with the high aspect ratio using copper without defects through the common vertical electroplating equipment; and
3. The method of the present disclosure can be used under DC/pulse power supply and the vertical electroplating equipment with a wide range of applications and strong adaptability.

### BRIEF DESCRIPTION OF THE DRAWINGS

FIG. 1 shows a scanning electron microscope (SEM) image of a copper seed layer in Embodiment 1 of the present disclosure;

FIG. 2 shows a SEM image of an electroplated copper layer in Embodiment 1 of the present disclosure.

FIG. 3 shows a scanning electron microscope (SEM) image of a copper seed layer in Embodiment 11 of the present disclosure;

FIG. 4 shows a SEM image of an electroplated copper layer in Embodiment 11 of the present disclosure.

### DETAILED DESCRIPTION OF THE EMBODIMENTS

In order to for the objective, the technical solution, and the advantages of the present disclosure to be clear and definite, the present disclosure will be further described below in detail in conjunction with the accompanying drawings and specific embodiments. However, the protection scope of the present disclosure is not limited to these embodiments. In the specification, the same reference numerals always represent the same elements, and similar reference numerals represent similar elements.

In the description of the present disclosure, it should be noted that terms, such as “upper”, “lower”, “front”, “rear”, “left”, “right”, “lateral”, “vertical”, “top”, “bottom”, “inner”, and “outer”, indicate orientations or positional relationships based on orientations or positional relationships shown in the accompanying drawings. These terms are merely used to easily describe the present disclosure and simplify the description of the present disclosure, rather than indicating or implying that a referenced device or element should have a particular orientation or be constructed and operated with a particular orientation, and therefore should not to be understood as a limitation of the present disclosure.

A method of advanced packaging and interconnection of through silicon vias (TSVs) with a high aspect ratio comprises the following steps:
1. depositing a copper seed layer: depositing a copper seed layer on a surface of the TSVs of a sample using physical vapor deposition (PVD);
2. plasma treatment: performing a plasma treatment on the sample treated in the step 1;
3. electroplating copper for filling: electroplating the sample treated in the step 2.

The sample is a breakout board for packaging with the TSVs. Hole diameters of the TSVs are less than 5 μm, and an aspect ratio of the TSVs are greater than 10.

The copper seed layer in the step 1 is deposited using a PVD device. A Ti layer with a thickness of 50-3000 nm as a barrier layer is firstly deposited, and the copper seed layer with a thickness of 50-5000 nm is then deposited.

The performing plasma treatment in the step 2 comprises performing plasma treatment for 3-7 minutes.

The electroplating in the step 3 comprises electroplating the sample treated in the step 2 with a current density of 0-4 amps/dm² (A/dm²) for 30-60 minutes at a temperature of 20-30° C.

An electroplating solution for electroplating copper using the method of the advanced packaging and interconnection of TSVs with the high aspect ratio comprises sulfuric acid, copper sulfate, chloride ions, brightener, inhibitor, and leveler.

The leveler is at least one of an onium salt or a polyamine.

A concentration of the copper sulfate is 80-300 g/L, a concentration of the sulfuric acid is 20-120 g/L, and a concentration of the chloride ions is 10-200 ppm.

The brightener is a mixture of one or more of poly (sodium 3,3′-dithiodipropane sulfonate), sodium thiazolinyl dithio propane sulfonate, sodium alcohol sulfur propane sulfonate, sodium 3-sulfhydryl-1-propane sulfonate, sodium dimethylformamide propane sulfonate, or sodium 3-[[(dimethylamino)thioxomethyl]thio]propane sulphonate, and a concentration of the brightener is 0.5-100 ppm.

The inhibitor is a mixture of one or more of polyethylene glycol, polypropylene glycol, expandable polyethylene 2000 (EPE2000), expandable polyethylene 2900 (EPE2900), or expandable polyethylene 3500 (EPE3500), and a concentration of the inhibitor is 10-1000 ppm.

The leveler is a mixture of one or more of tetrazolium red, thiosalicylic acid, S-methylisothiourea sulfate, 1,3-dimethyl-2-imidazolidinone, pyrimidine derivatives, onium salts, polyamines, or phenazine dyes, and a concentration of the leveler is 0.5-100 ppm.

When the leveler is the onium salt, the onium salt comprises a carbonium salt or a phosphonium salt.

When the onium salt is carbonium salt, the carbonium salt comprises one or more of a five-membered ring or a six-membered ring. When the five-membered ring or the six-membered ring is a heterocyclic ring, the heterocyclic ring comprises one or more of C, N, O, or S atoms. The five-membered ring or six-membered ring is connected to at least one of alkyl, phenyl, or alkenyl, and the five-membered ring or six-membered ring has positive charges of no less than one. When the onium salt is the phosphonium salt, a group connected to phosphorus in the phosphonium salt is an alkyl, benzene ring, or olefin.

When the leveler is the polyamines, the polyamines comprise a polyquaternary ammonium salt, wherein an N atom of a single chain molecule of the polyquaternary ammonium salt is positively charged, and the polyquaternary ammonium salt has a molecular weight of 10000-40000 and contains a carbon-carbon double bond.

### Embodiment 1

A method of advanced packaging and interconnection of through silicon vias (TSVs) with a high aspect ratio is provided. The method comprises the following steps:
1. depositing a copper seed layer: depositing a Ti layer as a barrier layer with a thickness of 100 nm and then depositing a copper seed layer with a thickness of 100 nm on a surface of the TSVs using a physical vapor deposition (PVD), and an observed result of the copper seed layer is shown in FIG. 1;
2. plasma treatment: performing the plasma treatment on the sample treated in the step 1 for 5 minutes;
3. electroplating copper for filling: electroplating the sample treated in the step 2.

A composition of 15 L of an electroplating solution for the aforementioned the electroplating copper in the step 3 is prepared as follows: 200 g/L of copper sulfate, 70 g/L of sulfuric acid, 60 ppm of chloride ions, 200 mg/L of polyethylene glycol with a molecular weight of 8000, 10 mg/L of the sodium 3-[[(dimethylamino)thioxomethyl]thio]propane sulphonate, and 50 ppm amino black 10B (used as the leveler). The polyethylene glycol with the molecular weight of 8000, the sodium 3-[[(dimethylamino)thioxomethyl]thio]propane sulphonate, and the amino black 10B (i.e., the leveler) are respectively prepared into concentrated solutions with concentrations of 100 g/L, 1 g/L, and 1 g/L respectively. 50 mL of deionized water is added into a beaker, 98 wt % of sulfuric acid is slowly added while stirring to obtain a solution, copper sulfate is added while the solution is hot and is stirred until the copper sulfate is dissolved. After cooling to room temperature (e.g., 20-25° C.), 37 wt % hydrochloric acid, the concentrated solutions of the polyethylene glycol with the molecular weight of 8000, the sodium 3-[[(dimethylamino)thioxomethyl]thio]propane sulphonate, and the amino black 10B (i.e., the leveler) are added to obtain a mixture. The mixture is transferred to a volumetric flask, and 50 mL of deionized water is added to a preset volume to obtain the electroplating solution.

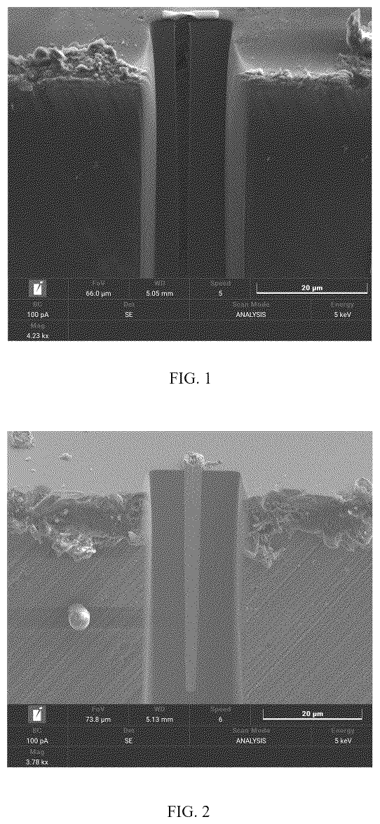

The electroplating solution is added to an electrolytic cell. A cathode plate of the electrolytic cell is a 6-inch wafer with TSVs having diameters of 3 μm and an aspect ratio of 15:1, a current applied to the electroplating solution has a current density of 0.3 amps/dm² (A/dm²), a time in which the current is applied is 45 minutes, a temperature of the electrolytic cell is 25° C., and a circulation rate of the electroplating solution is 15 L/minute. After being electroplated, the 6-inch wafer is washed with water, dried by blowing, and sliced into slices. An observed result of a copper layer plated inside of the TSVs is shown in FIG. 2 and Table 1.

### Embodiment 2

A method of advanced packaging and interconnection of through silicon vias (TSVs) with a high aspect ratio is provided. Embodiment 2 differs from Embodiment 1 in that the leveler is changed to tropylium tetrafluoroborate with a concentration of 15 ppm.

An observed result of a copper layer plated inside of the TSVs is shown in Table 1.

### Embodiment 3

A method of advanced packaging and interconnection of through silicon vias (TSVs) with a high aspect ratio is provided. Embodiment 3 differs from Embodiment 1 in that the leveler is 30 ppm of 1,3-dimesitylimidazol-2-ylidene.

An observed result of a copper layer plated inside of the TSVs is shown in Table 1.

### Embodiment 4

A method of advanced packaging and interconnection of through silicon vias (TSVs) with a high aspect ratio is provided. Embodiment 4 differs from Embodiment 1 in that the brightener is sodium thiazolinyl dithio propane sulfonate with a concentration of 25 ppm.

An observed result of a copper layer plated inside of the TSVs is shown in Table 1.

### Embodiment 5

A method of advanced packaging and interconnection of through silicon vias (TSVs) with a high aspect ratio is provided. Embodiment 5 differs from Embodiment 1 in that the inhibitor is EPE2900 with a concentration of 500 ppm.

An observed result of a copper layer plated inside of the TSVs is shown in Table 1.

### Embodiment 6

A method of advanced packaging and interconnection of through silicon vias (TSVs) with a high aspect ratio is provided. Embodiment 6 differs from Embodiment 1 in that the inhibitor is polyethylene glycol with a molecular weight of 10000 and a concentration of 500 ppm.

### Embodiment 7

A method of advanced packaging and interconnection of through silicon vias (TSVs) with a high aspect ratio is provided. Embodiment 7 differs from Embodiment 1 in that the brightener is sodium dimethylformamide propane sulfonate with a concentration of 5 ppm.

### Embodiment 8

A method of advanced packaging and interconnection of through silicon vias (TSVs) with a high aspect ratio is provided. Embodiment 8 differs from Embodiment 1 in that the copper sulfate is 80 g/L, the sulfuric acid is 210 g/L, chloride ions are 50 ppm, and the leveler is 1,3-dimesitylimidazol-2-ylidene with a concentration of 50 ppm.

### Embodiment 9

A method of advanced packaging and interconnection of through silicon vias (TSVs) with a high aspect ratio is provided. Embodiment 9 differs from in Embodiment 1 in that the leveler is tropylium tetrafluoroborate with a concentration of 30 ppm, and the circulation rate of the electroplating solution is increased to 20 L/minute.

### Embodiment 10

A method of advanced packaging and interconnection of through silicon vias (TSVs) with a high aspect ratio is provided. Embodiment 10 differs from in Embodiment 1 in that the leveler is tropylium tetrafluoroborate with a concentration of 100 ppm, and the circulation rate of the electroplating solution is 6 L/minute.

### Embodiment 11

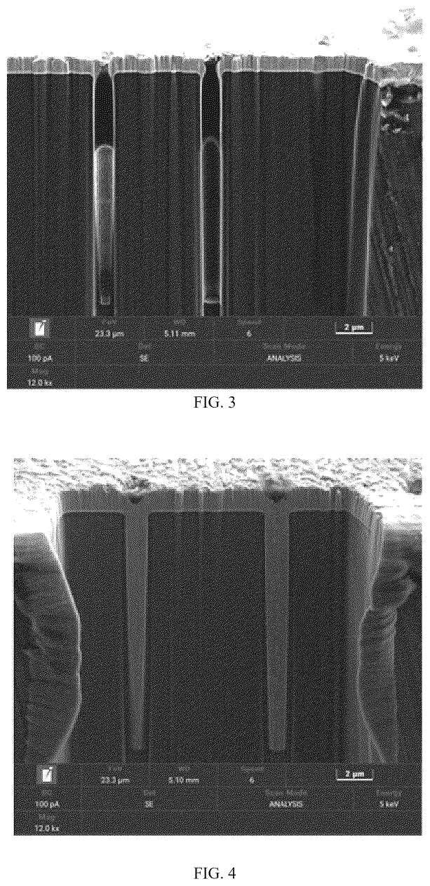

Embodiment 11 differs from in Embodiment 1 in that in through silicon vias (TSVs), although an aspect ratio of the TSVs are only 10, even if 1 μm of a copper seed layer is deposited in the TSVs using a physical vapor deposition (PVD), “pinch off” phenomenon occurs on openings of the TSVs due to diameters of the TSVs being 1.3 μm. At this time, the diameters of the TSVs are reduced to 0.55 μm from 1.3 μm, and depths of the TSVs are increased to 14 μm from 13 μm. The aspect ratio is increased to 25.5 from 10, which exceeds 25, and the TSVs with a high aspect ratio are transformed into TSVs with an ultra-high aspect ratio. A thickness of the copper seed layer on side walls and bottoms of the TSVs is 50 nm, and the TSVs have small tops and large bottoms. An observed result of the copper seed layer is shown in FIG. 3.

The composition of the electroplating solution for the aforementioned electroplating copper is prepared as follows: 220 g/L of copper sulfate, 40 g/L of sulfuric acid, 60 ppm of chloride ions, 500 mg/L of polyethylene glycol with a molecular weight of 8000, 5 mg/L of the sodium 3-[[(dimethylamino)thioxomethyl]thio]propane sulphonate, and 5 ppm amino black 10B (used as the leveler). A current density is 0.2 amps/dm² (A/dm²) for 20 minutes. An observed result of a copper layer plated inside of the TSVs is shown in FIG. 4.

TABLE 1
shows the filling situation of the copper plating
layer in the TSVs of Embodiments 1-5

| Embodiments | filled situation |
|---|---|
| Embodiment 1 | filled without defects |
| Embodiment 2 | filled without defects |
| Embodiment 3 | filled without defects |
| Embodiment 4 | filled without defects |
| Embodiment 5 | filled without defects |

The aforementioned embodiments are merely used to describe the technical solution of the present disclosure instead of limitations the present disclosure. The present disclosure is described in detail according to the aforementioned embodiments, and it is should be known by persons of ordinary technical skill in the art that the technical solution described in the various embodiments can be modified or some or all of the technical features in the various embodiments can be replaced by equivalents, wherein spirit of corresponding technical solutions of the modifications and the equivalents will not the depart from the scope of the technical solution of the various embodiments of the present disclosure.

What is claimed is:

1. A method of advanced packaging and interconnection of through silicon vias (TSVs) with high aspect ratio, comprising steps of:
(1) depositing a copper seed layer on a surface of the TSVs of a sample using physical vapor deposition (PVD), an aspect ratio of the TSVs is greater than 10;
(2) performing a plasma treatment on the sample treated in the step 1; and
(3) electroplating the sample treated in the step 2.

2. The method according to claim 1, wherein:
the sample is a breakout board for packaging with the TSVs,
hole diameters of the TSVs are less than 5 μm.

3. The method according to claim 1, wherein:
the depositing the copper seed layer in the step 1 comprises:
depositing a Ti layer with a thickness of 50-3000 nm as a barrier layer, and
depositing the copper seed layer with a thickness of 5-5000 nm over the Ti layer.

4. The method according to claim 1, wherein:
the performing plasma treatment in the step 2 comprises performing plasma treatment for 3-7 minutes.

5. An electroplating solution for electroplating copper using the method according to claim 1, wherein the electroplating solution comprises sulfuric acid, copper sulfate, chloride ions, a brightener, an inhibitor, and a leveler.

6. The electroplating solution according to claim 5, wherein:
a concentration of the copper sulfate is 80-300 g/L,
a concentration of the sulfuric acid is 20-120 g/L,
a concentration of the chloride ion is 10-200 ppm,
a concentration of the brightener is 0.5-100 ppm,
a concentration of the inhibitor is 10-1000 ppm, and
a concentration of the leveler is 0.5-100 ppm.

7. The electroplating solution according to claim 5, wherein the leveler comprises at least one of an onium salt or a polyamine.

8. The electroplating solution according to claim 7, wherein:
the onium salt comprises a carbonium salt or a phosphonium salt,
when the onium salt is the carbonium salt:
the carbonium salt comprises one or more of a five-membered ring or a six-membered ring;
when the five-membered ring or the six-membered ring is a heterocyclic ring, the heterocyclic ring comprises one or more of C, N, O, or S atoms;
the five-membered ring or six-membered ring is connected to at least one of alkyl, phenyl, or alkenyl; and
the five-membered ring or six-membered ring has positive charges of no less than one; and
when the onium salt is the phosphonium salt, a group connected to phosphorus in the phosphonium salt is an alkyl, benzene ring, or olefin.

9. The electroplating solution according to claim 7, wherein:
when the leveler is the polyamine, the polyamine comprises a polyquaternary ammonium salt, wherein an N atom of a single chain molecule of the polyquaternary ammonium salt is positively charged, and the polyquaternary ammonium salt has a molecular weight of 10000-40000 and contains a carbon-carbon double bond.

10. The electroplating solution according to claim 5, wherein:
the brightener is a mixture of one or more of poly (sodium 3,3′-dithiodipropane sulfonate), sodium thiazolinyl dithio propane sulfonate, sodium alcohol sulfur propane sulfonate, sodium 3-sulfhydryl-1-propane sulfonate, sodium dimethylformamide propane sulfonate, or sodium 3-[[(dimethylamino)thioxomethyl]thio]propane sulphonate; and
the inhibitor is a mixture of one or more of polyethylene glycol, polypropylene glycol, expandable polyethylene 2000 (EPE2000), expandable polyethylene 2900 (EPE2900), or expandable polyethylene 3500 (EPE3500).

11. The method according to claim 1, wherein:
the electroplating in the step 3 comprises electroplating the sample treated in the step 2 with a current having a current density of 0-4 amps/dm² (A/dm²) for 30-60 minutes at a temperature of 20-30° C.
